(19) United States
(12) Patent Application Publication
(10) Pub. No.: US 2011/0134040 A1
(43) Pub. Date: Jun. 9, 2011

(54) OPTICAL NAVIGATION DEVICE

(76) Inventors: Jacques Duparre, Jena (DE); Peter Dannberg, Jena (DE); Andreas Bräuer, Schloben (DE)

(21) Appl. No.: 12/671,816

(22) PCT Filed: Aug. 18, 2008
(86) PCT No.: PCT/EP08/06780

§ 371 Date: Feb. 22, 2011

(30) Foreign Application Priority Data
Sep. 10, 2007 (DE) 10 2007 042 984.5

(51) Int. Cl. G09G 5/08; H01L 27/146; G06K 9/20

(52) U.S. Cl. 345/166; 250/208.1; 382/312

(57) ABSTRACT

A device for optical navigation, containing an image sensor which has a large number of image sensor units which are disposed in an array-like manner with respectively at least one light-sensitive surface and at least one lens which is disposed between an object to be imaged and the image sensor. A microlens array is present, at least one microlens being assigned to one image sensor unit.

### BACKGROUND

The subject of the invention is a device for optical navigation according to the features of the preamble of the main claim.

Devices for optical navigation are used for carrying out, in data processing units, conversion of the movement of an input device, such as e.g. a computer mouse, relative to a reference surface or a reference object into the movement of a pointer on a display, e.g. of a computer, or mobile telephone or PDA.

In the case of devices for optical navigation, the so-called tracking surface, or also object plane, is thereby imaged by means of an objective lens on a digital image sensor. At the same time, the object plane is illuminated laterally by means of a laser or LED and corresponding beam formation. The image recording takes place successively in a rapid sequence (1500 to 6,000 per second). The successively recorded images are correlated with each other and the mutual displacement of the images is used as a measure of the width and speed of the displacement of the input device relative to the tracking surface (or vice versa). This is converted in turn into the movement of a point on the display. A computer mouse with a device for optical navigation, as described in the above section, is shown for example in U.S. Pat. No. 6,967,321 B2 or U.S. Pat. No. 7,045,775 B2.

In the case of the devices for optical navigation according to the state of the art, problems arise however with further miniaturisation of the optical structure: in the case of a given diagonal of the image sensor and a reduction in the spacing between the plane of the image sensor and the object plane, the outer image regions are situated at very large angles relative to the optical axis of the lens. As a result, the resolution and brightness at the edge areas of the image sensor is impaired.

It is the object of the present invention to make available a device for optical navigation which, even with increasing miniaturisation and increasing shortening of the spacing between image plane and object plane even in the edge regions of the image sensor, good resolution and brightness is conferred at the edge of the image sensor.

### SUMMARY

The object is achieved by a device according to the features of the main claim. As a result of the fact that a large number of lenses, which are configured as a microlens array, is present and respectively at least one microlens is assigned to an image sensor unit of the image sensor, it is possible that the microlens assigned to an image sensor unit transmits a part of the object part to be imaged essentially “on-axis”, i.e. each microlens images only a partial region of the object onto the image sensor unit and the light-sensitive surfaces situated therein, which leads in the combination of the large number of array-like image sensor units to the fact that object and image parts are situated essentially directly opposite each other, i.e. no reversed but rather upright imaging of the object is involved.

As a result of the fact that an object part situated opposite an image sensor unit is situated along the optical axis of the assigned microlens, the image sensor can be brought virtually as close as desired to the object plane since the angle region of the microlens of an image sensor unit, which is to be imaged, is very narrow, similar to a compound eye of an insect. With an arrangement of this type, the resolution is improved in particular at the edge of the image sensor and the light intensity does not reduce in the region of the image sensor since no strong natural vignetting occurs at the image edge.

Because of the improved imaging properties of the image sensor, the device for optical navigation can be equipped with a lower number of light-sensitive surfaces or pixels since in fact each pixel can image only a very small angle region, this however in an exceptionally good manner. Therefore fewer light-sensitive surfaces are required in order to compensate for a correction with respect to vignetting. Likewise, it is not required to configure the spacing of the light-sensitive surfaces to be very small (it may in fact be the case that it is desired that the image sensor turns out to be very small) since the surface of the image sensor can image an object field which is essentially equally large virtually without resolution losses.

Since the current image sensors are produced with lithographic structuring techniques, at least one microlens array can be applied during production of the individual image sensor units or image sensor unit array in such a manner that said microlens array is assigned to the image sensor arm and/or is situated thereon and connected to the latter. In this way, a large number of sensors can be produced in a short time. The production is thereby effected advantageously on a wafer scale.

It is advantageous if the microlenses are aligned relative to each other in such a manner that their optical axes extend parallel to each other. In this way, overlaps of the object regions imaged onto the individual sensor units can be kept low (as a function of the angle region of the microlens which can be imaged), and it is possible in addition in a simple manner to produce a 1:1 imaging of the object field on the image sensor. The microlenses thereby advantageously image an object field region onto the image sensor unit, which object field region is precisely as large as the spacing of the microlenses or detector pixels themselves. Furthermore, it is advantageous if the optical axes of the individual microlenses are essentially perpendicular to the object plane. In this way, the object field points recorded by the image sensor units for each image sensor unit are virtually at the same spacing. As a result, good conditions are offered in that the illumination conditions of the object field for each image sensor unit are essentially the same or not distorted by distance effects of the individual image sensor units.

As an alternative to the preceding implementations, the optical axes of the microlenses can become increasingly more inclined from the centre of the image sensor to the edge regions, in the sense that the optical axis of a microlens is taken in the centre of the image sensor as reference point, the surrounding optical axes of the microlenses are inclined slightly outwards or inwards. As a result of the inclined design of the optical axes, a deviation from a 1:1 imaging can be achieved and a smaller object field can be produced on a larger image sensor (by inclining the optical axis inwards) or a larger object field on a smaller image sensor (by inclining the optical axis outwards). With increasing inclination of the optical axes, effects, such as astigmatisms or image field curvatures, must however be taken into account also with the designs of the microlens, which is however already known in the state of the art. However, it must be ensured in particular that, in the desired operating spacing, the object field regions assigned to the individual image sensor units abut against each other and no gaps are produced between these, with which the edge length of an object field region assigned to an image sensor unit is greater than the spacing of the microlenses. The operating spacing between object plane and image sensor is, according to the invention, of an order of magnitude between 0.1 mm to 1 mm or 0.1 mm up to a few metres.

It is particularly advantageous if the microlenses are aligned relative to each other in such a manner and configured in such a manner that the object field portions of adjacent microlenses do not overlap, i.e. are separate from each other. Particularly advantageously, no gap is situated either between the object field regions of two adjacent microlenses so that the object field in its entirety can be transmitted on the image sensor without redundant information. With the help of the microlenses, the object field regions are imaged onto the light-sensitive surfaces, the light-sensitive surfaces being able to be substantially smaller than the imaged object region without the global 1:1 imaging being eliminated.

Furthermore, it is advantageous if an image sensor unit is connected to at least one microlens by means of an optically transparent substrate, the substrate being able to be manufactured from the same material as the microlens but not requiring to be. In this way, fewer optical transition surfaces are produced, which simplifies calculation of the beam path and in addition gives the arrangement of the microlenses on the image sensor units a simpler configuration. In this way, reflections are avoided, which leads to a better light yield.

It is a further advantageous development of the device if, between a microlens and the light-sensitive surface of the image sensor unit, at least one (transparent) pin diaphragm in an opaque material (or an opaque layer) is disposed. By means of the pin diaphragm, an additional mechanism can be inserted in order to image exclusively the light from the object field part to be imaged onto the light-sensitive surface assigned to this object field portion. Light, which is incident on the microlens from other directions and hence could impinge on a further light-sensitive surface assigned to the adjacent image sensor unit, is suppressed (or absorbed) by the pin diaphragm layer and hence crosstalk between adjacent image sensor units is prevented. In the case of a 1:1 imaging (vertical optical axes), the pin diaphragms are centred with the respective lenses and detector pixels.

It is a possible embodiment of the microlens arrangement relative to the image sensor units if the microlenses are disposed in a large number, preferably two, particularly preferably three, of microlens arrays situated one above the other. Respectively one microlens of the first microlens array is thereby situated with a microlens of the second or third microlens array such that the microlenses are aligned. The arrangement of the microlenses to form a Gabor superlens is particularly advantageous. In this variant of the device for optical navigation, furthermore, an object field portion situated opposite an image sensor unit is imaged on said object field portion, however not only the microlenses placed in the connection line between object field portion and image sensor unit contribute to the imaging of the object field part, but also microlenses which are adjacent to this microlens. By means of a suitable arrangement of the plurality of microlens arrays, a plurality of optical channels formed by the microlenses contribute at the same time to the imaging of an object field portion onto a light-sensitive surface. The advantage resides in the fact that such a microlens arrangement intensifies the light significantly more than in the presence of essentially only one microlens array since not only one optical channel but a large number of optical channels contribute here to the formation of an object field part on the light-sensitive surface.

Particularly advantageously, the microlens arrays are fitted such that, between a first (or second) microlens array and a second (or third) microlens array, a spacing array with openings which are transparent in the direction of the optical axis is introduced, mutually adjacent microlenses being extensively optically isolated transversely relative to the optical axis of the microlenses relative to each other. In this way, crosstalk within the channels which is undesired in this case is likewise essentially prevented. In this variant, the correct overlapping of a plurality of partial images is taken into account in order to achieve the increased light intensity. Light from the second lens of the one channel should not reach the third lens of the adjacent channel of the microlens array situated thereunder, which can be achieved by optically dense walls between these microlens arrays. At the same time, the first and second microlens array are fixed at the desired spacing relative to each other.

Another alternative of the microlens arrangement to the image sensor is to assign a microlens exclusively to one image sensor unit, an image sensor unit preferably having a single light-sensitive surface. This arrangement corresponds essentially to the apposition principle, the individual lenses being disposed in one plane contrary to an insect eye and not along a curved surface. The arrangement is particularly advantageous if the optical axis of a microlens is essentially perpendicular to the light-sensitive surface of the image sensor unit which is assigned thereto. The advantage of such a microlens arrangement resides in its very simple construction so that this navigation sensor can be produced rapidly and economically on a wafer scale, e.g. with lithographic and replication technologies.

Another alternative of the microlens arrangement to the image sensor is to assign a microlens exclusively to one image sensor unit, an image sensor unit preferably having a single light-sensitive surface. This arrangement corresponds essentially to the apposition principle, the individual lenses being disposed in one plane contrary to an insect eye and not along a curved surface. The arrangement is particularly advantageous if the optical axis of a microlens is essentially perpendicular to the light-sensitive surface of the image sensor unit which is assigned thereto. The advantage of such a microlens arrangement resides in its very simple construction so that this navigation sensor can be produced rapidly and economically on a wafer scale, e.g. with lithographic and replication technologies.

It is particularly advantageous if the device for optical navigation has an incoherent or coherent optical beam source which is assigned to the image sensor in the sense that the beam source irradiates the object field to be imaged on the image sensor. This takes place advantageously in incident light mode, i.e. from the same half-space relative to the tracking surface (i.e. the object field) in which the imaging system is also situated. In particular a spectrum of the beam source is hereby advantageous, which moves in the visible range between 350 to 759 nm or in the near UV—up to 200 nm or near infrared range up to 1,300 nm. This is necessary in particular if a uniform illumination of the object field to be imaged is not possible by natural light sources. In the case of incoherent illumination, a light diode is advantageously used, which light diode is fitted from the side at as small an angle as possible relative to the object field to be imaged in order that the structure of the object field results in shadows which can then be imaged on the image sensor by means of the microlenses. In this way, image information or modulation can be brought into an otherwise virtually texture-free object plane. In the case of coherent illumination, advantageously a laser diode is used, in the case of which an inclined incidence of the illumination is tolerable since a speckle pattern is produced above the object plane by coherent scattering, which pattern can be detected by the image sensor. It should hereby be noted that the object plane of the arrangement is no longer the tracking surface but the speckle field scattered back or produced by it. The speckle field is formed by interference of adjacent scattered bundles typically at a spacing of approx. 1 mm from the tracking surface.

In order to undertake as efficient illumination as possible by means of the beam sources, the beam source can be irradiated onto the object field by means of a deflection lens system or a collector lens system. It is also sensible to introduce light guides into the image sensor, for example between the individual light-sensitive surfaces, which light guides decouple the light in the direction of the object field to be imaged.

The radiation source and the image sensor microlens arrangement are disposed preferably on a common carrier so that the carrier can be installed and removed as a common module. The carrier can be an electronic component, such as e.g. a printed circuit board. In this way, the illumination of an object field can be established already by the arrangement of the illumination for the image sensor.

Advantageously, the image sensor has a surface extension of 0.25 μm to 10 mm² or between 100 and 10,000 image sensor units, preferably between 100 and 1,000 image sensor units. In this way, although there is already high miniaturisation of the image sensor, good results can be produced with adaptation to different object field sizes.

### BRIEF DESCRIPTION OF THE DRAWINGS

The device according to the invention for optical navigation is intended to be explained subsequently with reference to some embodiments and Figures. There are shown:

FIG. 1 device according to the invention for optical navigation with image sensor microlens array and beam source;

FIG. 2 image sensor with microlens array configured as apposition image sensor;

FIG. 3 image sensor with Gabor superlens.

### DESCRIPTION OF PREFERRED EMBODIMENTS

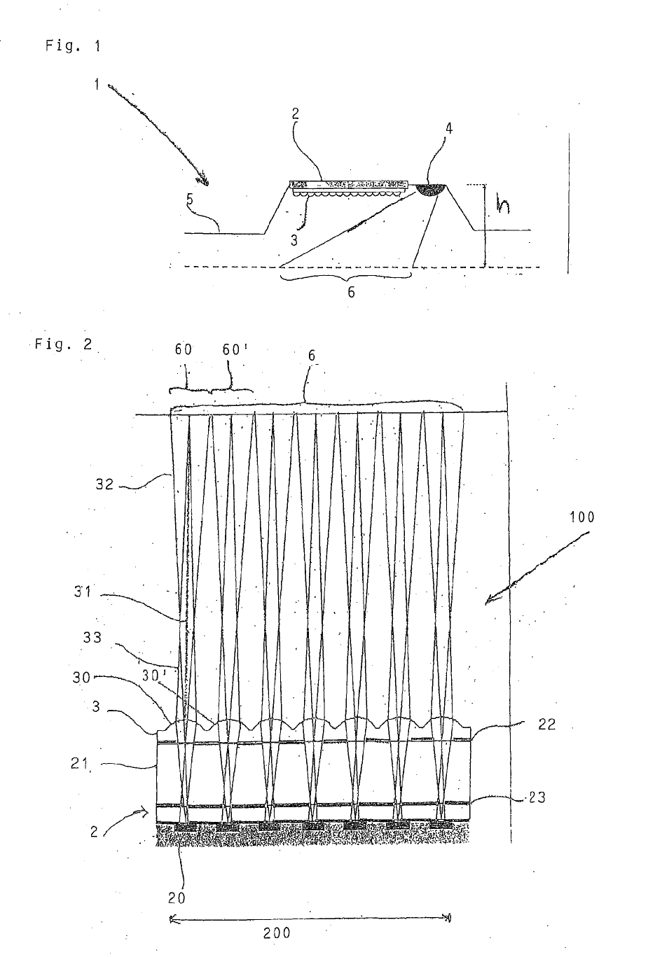

FIG. 1 shows an input device 1 according to the invention, as can be produced for example in a computer mouse or a remote control, which device has an image sensor 2 on which a microlens array 3 is fitted. Furthermore, a beam source 4 in the form of an LED is present, both the beam source 4 and the image sensor 2 being disposed on a carrier 5. The object field 6 which is scanned with the input device 1 is situated directly below the microlens array 3.

A pattern which is situated in the object field 6 is illuminated by the beam source 4 such that a point-wise image is produced on the image sensor 2 by means of the microlens array 3. As an alternative to an LED, also a coherent light source, such as for example a laser diode, can be used, no shadow being generated on the object field 6 with said laser diode but a speckle pattern which is produced by interferences of the coherent light, said speckle pattern being visible above the tracking surface and being able to be detected by the image sensor 2.

Typically, the object field 6 has the same size as the image sensor 2 or the microlens array 4 so that a 1:1 imaging is produced. This has the advantage that the microlens array 3 can be disposed on the image sensor such that the optical axes of the microlenses are essentially perpendicular to each individual image sensor unit of the image sensor 2. This means in particular that the part of an object field 6 which is imaged onto an image sensor unit of the image sensor 2 is situated directly vertically below the image sensor unit. In addition, an equal distance of the image sensor units from the parts of the object field 6 can be produced in this way. In the illustration shown here, the spacing h between object field and image sensor is between 0.5 mm and 2 mm.

There is possible as carrier an electronic component which—after image sensor and illumination have been applied on the latter—is positioned simply on a device, e.g. a mouse.

In the following, the mode of operation of the input device 1 according to the invention is intended to be dealt with briefly. The carrier 5 is moved over the plane in which the object field 6 is situated so that the image sensor perceives and has in the object field various sections of the plane. The image sensor thereby records images of the imaged object field in a rapid sequence, compares these with previously recorded images and thus in this way can establish whether the input device has moved to the left, to the right, forwards or backwards. Of course, the reverse case is also possible that the input device 1 does not move but rather the plane situated thereunder. There may be mentioned here by way of example a navigation sensor according to the invention which is used as Eyetracker, i.e. sits in a fixed position and records the movements of the eye, the eye moving constantly. The movement of the eye can thereby be converted into the movement of a pointer or operation of a robot arm. Similarly, the navigation sensor can be inserted into a remote control, movements of the remote control being converted into movements of a cursor on a monitor or television.

The optical navigation sensor shown here in the input device 1 is predestined to be used on a wafer scale. Economical production and assembly is thus possible. Both the image sensor 2 and the microlens array 3 and also the connection thereof can be produced on a wafer scale. This applies, including the assembly of the individual components, to the optical navigation sensor. Furthermore, separation of the individual sensors is possible by means of wafer saws (since sensors have very much more space on a wafer). The separation is hence virtually the last production step, it also being sensible as an alternative, because of self-adjusting effects, to implement the assembly in elements with simple adjustment and assembly automatic machines.

Two variants of the image sensor microlens arrangements are intended to be referred to subsequently, which variants are particularly relevant for the invention.

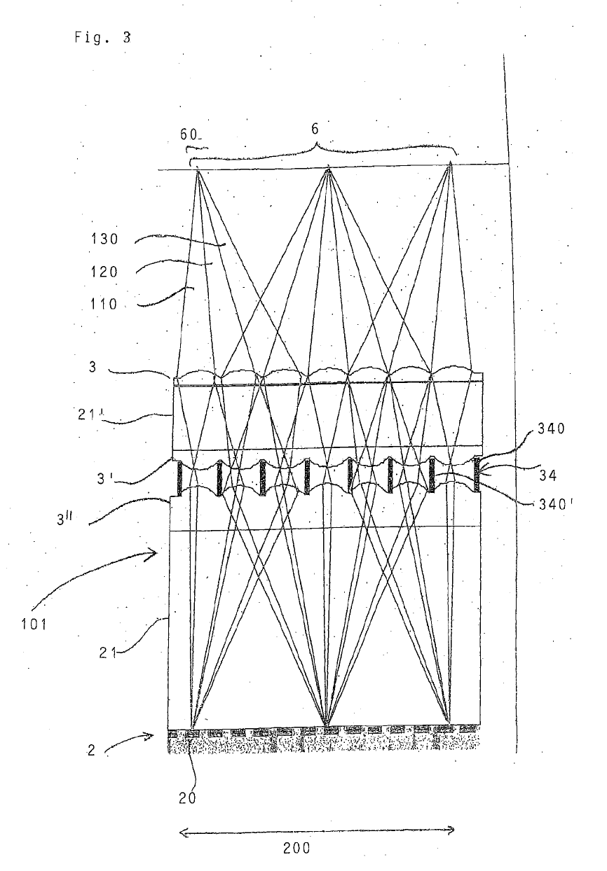

In FIG. 2, an image sensor microlens arrangement with apposition lens 100 is shown. Together, they produce an optical navigation sensor. The actual image sensor 2 has a large number of image sensor units, 20′ which include photodiodes or detection pixels. There is applied on the arrangement of the image sensor a beam-permeable substrate 21 made of glass or porcelain or plastic material, a first pin diaphragm array 22 and a second pin diaphragm array 23 being present in the substrate. Above the first pin diaphragm array 22, the microlens array 3 which is made of glass or plastic material and is connected to the substrate is situated. In the microlens array 3 there is situated a large number of microlenses 30, precisely one detection pixel being assigned here to each microlens 30, i.e. a light-sensitive surface of the image sensor unit 20. The large number of microlenses 30 thereby has a total width 200 which is exactly as wide as the object field 6 to be imaged. The optical axis 31 of a microlens 30 is perpendicular to the light-sensitive surface 20. This means in particular that the part 60 of the object field 6 is imaged onto the detector pixel situated directly opposite.

Two adjacent microlenses, e.g. 30 and 30′, are thereby configured such that the parts 60 or 60′ of the object field 6 which the microlenses image onto the light-sensitive surfaces situated behind essentially do not overlap and no gap produced between them either. It is ensured in this way that the entire object field 6 is imaged in parts (e.g. 60, 60′) resolved onto the image sensor units, each image sensor unit having exactly one pixel and hence an upright image being generated on the image sensor 2, in contrast to a single large lens in the case of which a reverse imaging takes place according to the laws of geometric optics.

In FIG. 2, the optical axes 31 of the microlenses 30 respectively are parallel to the adjacent lenses. As a result of the fact that oppositely situated parts of the object field 6 are imaged onto the individual light-sensitive surfaces of the image sensor 2, only light beams from a small angle region impinge on the light-sensitive surface 20. This is intended to be explained with reference to the microlens 30, the part 60, imaged by the latter, of the object field 6 and the light-sensitive surface 20 situated thereunder.

As a result of the imaging by the microlens array 3 and the screening of the edge and intermediate regions of the microlens array by the first pin diaphragm array 22, only specific light beams can impinge on the light-sensitive surface. This relates in particular to the light beams of the part 60 of the object field 6 if, by means of the additional pin diaphragm layer 23, crosstalk from one lens to the detector pixels of the adjacent channel is prevented. This is shown by way of example on the main beams of the edge bundles 32 which represent the course through the microlens centre (or in the main plane: the cardinal point). These indicate that the object region recorded by a channel corresponds precisely to the photodiode size projected via the image- and object width of the microlens into the object plane. Reference may hereby be made to the fact that also the edge bundles are of course focused onto the pixels. However, only the marginal beams for the central bundle, and also the main beams for the edge bundles are illustrated. The course of the marginal beams (the focusing) can be deduced correspondingly from the course of the central bundle. The marginal beams 33 for vertical incidence show the imaging effect of the microlens and how the pin diaphragm arrays 22 and 23 permit passage of only specific regions so that it is herewith ensured in turn that the partial regions of the object field 6 which abut against the part 60 are covered by adjacent image sensor units.

As an alternative to the microlens arrangement shown in FIG. 2, the optical axes 31 can be inclined slightly towards the edge of the sensor, i.e. from the centre to the left and right edge, so that a global 1:1 imaging is no longer present and the imaged object field 6 is greater than the imaging-relevant part 200 of the image sensor 2. In this case, it must however be ensured that, at the desired operating spacing, the object field region assigned to an individual microlens abuts precisely against the object field region of an adjacent lens, which means that the edge length of an object field region assigned to a microlens is greater than the spacing of the microlenses from each other. As shown in FIG. 1, the operating spacing or object spacing according to the invention is of the order of magnitude of 0.1-1 mm or in general as optical navigation sensor of 0.1 mm to a few metres.

As an alternative, one of the pin diaphragm arrays 22 or 23 can be dispensed with. This reduces the quality of the image slightly but the actual advantage of the arrangement that the microlenses image an oppositely situated part of the object field onto the light-sensitive surface is however retained. This means in particular that the edge of the object field 6 is transmitted by other microlenses as the partial region in the centre of the object field 6. However, the partial region in the centre falls virtually perpendicularly to at least one microlens and the assigned image sensor unit.

By means of a correspondingly chosen number of diaphragm arrays in an axial arrangement and correspondingly chosen layer thicknesses of transparent intermediate layers, such as the layer 21 here, crosstalk of adjacent channels is suppressed extensively, which otherwise would lead to stray light and hence to reduction in the signal-to-noise ratio. At the same time, the size and position of the openings should however be such that the vignetting of the desired useful light is minimal in particular for the edge bundles of an individual optical channel.

In the variant of FIG. 2 and the variants related thereto, the light-sensitive surfaces 20 should be significantly smaller than the channel spacing so that a sensible resolution can be achieved, which leads however to a reduced filling factor of the detector pixels in the image sensor and to a comparatively reduced light intensity. In a more sensible mariner, densely packed large photodiodes should not be covered for this purpose with small diaphragms, instead the photodiodes should have the corresponding smallness from the beginning and the space between the photodiodes should be used for electronic circuits for meaningful image reading, signal amplification, increasing the sensitivity, improving the signal-to-noise ratio, for example by “correlated double sampling”, or in particular for image preprocessing, such as e.g. contrast calculation, measurement of the contrast direction, determination of the image displacement. If as an alternative to the image sensor shown in FIG. 2, a plurality of pixels is assigned to an individual microlens, the respectively recorded partial images must be rotated by 180° since now the result within an individual image sensor unit is a reversed, non-upright image.

Advantageously, the navigation sensor of FIG. 2 is produced on a wafer scale. This also includes the connection of image sensor to microlens array. Furthermore, a UV replication of the microlenses in polymer takes place on a glass substrate which is subsequently connected to the image sensor, or the entire or partial lens construction is hot-embossed and subsequently connected to the image sensor or the lens construction is constructed/assembled directly on the image sensor in layers by means of lithographic techniques and replications. Since a plurality of image sensors has space on individual wafers, they are separated later by means of a wafer saw but advantageously only after production of the complete layer construction. After separation of the modules (this can be merely the lens system or together with an image sensor), the sides must be blackened for example with absorbing epoxy in order to avoid lateral coupling of stray light through the substrate end faces of the substrate 21. In the case of a wafer-scale connection to the image sensor, a rear-side contacting by means of through-silicon vias is advantageous since otherwise the optical regions must be designed to be smaller than the regions of the image sensor 2 in order to keep the bonding pads free also for contacting. By means of a pedestal-like structuring of the spacer layer formed by the substrate 21 on the active region of the image sensor, the image sensor wafer can then be prevented from being damaged on the front side during sawing of the lens system.

In FIG. 3, an alternative arrangement which can be used within the scope of the optical navigation is presented. The image sensor microlens arrangement with Gabor superlens 101, shown here, has significantly more light intensity than the variant of FIG. 2 since, at the same time, a plurality of adjacently situated optical channels (which are formed hereby from the aligned microlenses of the microlens arrays 3, 3′ and 3″ contribute here to the formation of an image spot. In the illustration shown here, the spacing of the image sensor 2 from the object field 6 is approx. 600 μm. The construction is analogous to already known Gabor superlenses, but preferably without an otherwise normal difference there in centre spacings of the microlenses, which is sufficient for the imaging task present here.

In the case of the Gabor superlens with three microlens grids 3, 3′, 3″, the microlens grid 3 produces an intermediate image which is transmitted by the microlens array 3″ into the image plane situated in the plane of the light-sensitive surfaces. The microlens array 3′ thereby acts as field lens array. Preferably, a 1:1 imaging is produced within the microlens array arrangement 3, 3′, 3″. In the image plane, there is usually a plurality of light-sensitive surfaces, usually only one light-sensitive surface being disposed in the image plane of one channel.

On the image sensor 2, a substrate 21, for example made of transparent polymer, is applied, on which substrate in turn a microlens array 3″ is disposed. On the microlens array 3″, there is situated a spacer 34 which is transparent in the direction of the optical axes of the channels, but separates mutually adjacent optical channels from each other in an paque manner. A further microlens array 3′ is disposed on the spacer 34 and is connected in turn to a substrate 21′ and to a third microlens array 3. The thicknesses of the microlens arrays 3, 3′, 3″ and of the substrates 21, 21′ and of the spacer 34 are thereby chosen such that, as in the variant of FIG. 2, a part 60 of the object field 6 is imaged onto an oppositely situated image sensor unit 20. However, not only the microlenses which are situated in the direct connection line between the part 60 of the object field 6 and the image sensor unit 20 contribute, but also microlenses of adjacent channels. The images are thereby upright and overlap congruently because of the lens design.

Alternatively, a construction with only two microlens arrays is also conceivable, the image plane of the microlens array which is nearest to the object field, the so-called intermediate image plane, is the object plane of the then second microlens array. The third microlens array (provided here by the microlens array 3′) which is fitted in addition as shown in FIG. 3 is suitable for imaging all light from the apertures of the lenses of the first microlens array 3 in the apertures of the lenses of the second microlens array 3″.

The navigation sensor shown here shows an upright image in order to ensure that the different partial regions of the object field 6 are transmitted to the individual photodiodes 20, e.g. 1:1 in the correct position and orientation (i.e. overlapping). An optical channel is hereby formed by the microlenses of the microlens array 3, 3′, 3″ which are fitted in alignment (i.e. a plurality of optical channels are situated adjacently) and a partial region of the object field 6 is transmitted simultaneously by a plurality of channels. However, the partial regions of the object field 6 which are transmitted to different light-sensitive surfaces can be separated from each other.

The optically isolating spacer 34 prevents undesired crosstalk between the second and third lens of adjacent channels. The image sensor and a subsequent electronic unit (not illustrated here) convert subsequently recorded images into a pointer movement for example on a display. The intermediate image width and hence substrate thickness 21′ and the image width and hence substrate thickness of the second substrate 21, as also the spacing of second and third lens, are produced from the focal distances and focal distance ratios of the microlenses, the axial spacings thereof and the spacing of the object field or of a speckle field in the case of a coherent illumination for the microlens array 3 and also the size of the channel spacing for suppressing crosstalk from the first lens of one channel to the second lens of the adjacent channel through the first substrate 21′.

In the variant shown here, the pitch of the lenses is the same so that a 1:1 imaging is produced. However this can also be different, which can then result in an enlarged or reduced imaging, according to whether the lens array with the larger pitch is fitted in the lens system on the image- or object side and how the ratio of object- and image width is. Inclined optical axes which correspondingly connect object- and partial parts by means of the lens channels result therefrom.

The optically isolating spacer 34 has the form of a sieve. It comprises a perforated matrix in a plate which is between 10 μm and 500 μm thick, the diameter of the holes being less than the spacing thereof and the perpendicularly resulting webs being opaque either due to the material choice of the plate or due to the subsequent coating so that no optical connection occurs between adjacent channels.

Furthermore, the spacer helps with the self-centring of the two substrates or of the supported microlens arrays relative to each other, as a result of which a very simple and yet precise adjustment of the elements of the lens system relative to each other is possible. The pitch and the arrangement of the holes is thereby the same as that of the supported microlens arrays. Hence, also diameters of the holes are smaller than or equal to those of the supported lenses so that the lenses on the substrates engage on both sides into the holes, which forms a preferred form of the lateral and axial adjustment. The thickness of the plate results from the required spacing of the microlens array 3′ acting as field lenses relative to the second microlens array 3″ taking into account any required adhesive thickness. The arrangement can then be mounted with simple pick-and-place robots.

In this arrangement, there is no generally applicable fixed assignment of one optical channel to a detector pixel situated thereunder since a regular, closed image is produced, i.e. the arrangement of the optical lens channels, even with a square arrangement of the detector pixels, can be e.g. also hexagonal in order to achieve as high a packing density as possible of the channels and hence light intensity. Correspondingly, the pixel size and number of pixels of the image sensor need not be coordinated to the channel number and channel size. Therefore, a conventional image sensor 2 with tightly packed detector pixels can also be used in this variant of FIG. 3.

The size of the intermediate image is defined essentially by the thickness of the substrate 21′. It is hereby advantageously such that the size of the intermediate image is as small as possible relative to the channel spacing so that an object point can be transmitted simultaneously by as many optical channels as possible. This means in particular that the focal distance of the first microlens array 3 should be as short as possible. The radii of curvature of the lenses of the three lens arrays can in general be different. With suitable choice of the spacings and focal distance ratios, another 1:1 imaging within one channel is then also achieved. The pitch of the three lens arrays must however be the same for a global 1:1 imaging. There is therefore used with the variant of FIG. 3 a large “superpupil” which can extend ideally virtually over the entire microlens array, i.e. effectively a lens diameter which contributes to the object point transmission which and corresponds to that of a conventional miniature lens, without however having to accept a skewed beam passage for the outer object regions.

At the object edge, channels respectively other than central and edge channels now contribute as in the object centre, however due to the array-like continuation there is always a channel which transmits the object point at virtually perpendicular incidence and the adjacent channels still situated in the superpupil then correspondingly at slightly increased angles.

Preferably, the entire system is achieved by stacking on a wafer scale or by element-wise mechanical self-adjustment only of the lens system and subsequent rough lateral alignment relative to the image sensor and adhesion. Separation of the modules involves blackening of the sides for example with absorbing epoxy, as described already in FIG. 2. The spacer is produced in a stamping or etching process, or bored, also a lithographic structuring process, such as for example an SU8 photoresist on a carrier substrate is possible. The perforated foil produced therefrom is subsequently blackened. If the holes cannot be structured through the substrate, it can be achieved by rear-side grinding and polishing of the perforated plate or foil that the holes are completely open and the end faces have the correspondingly required surface quality.

### REFERENCE NUMBERS

Input device 1
Image sensor array 2
Microlens array 3, 3′, 3″
Beam source 4
Carrier 5
Object field 6
Image sensor unit 20
Beam-permeable substrate 21, 21′
First pin diaphragm array 22
Second pin diaphragm array 23
Microlens 30
Optical axis 31
Main beams 32
Marginal beams 33
Spacer 34
Object field section 60, 60′
Image sensor with apposition lens 100
Image sensor with Gabor superlens 101
First beam path 110
Second beam path 120
Third beam path 130
Viewing field 200
Separating wall 340, 340′

1. Device for optical navigation, containing an image sensor array (2) with a large number of image sensor units (20, 20′) disposed in an array-like manner with respectively at least one light-sensitive surface and also at least one microlens array (3; 3′, 3″) which is assigned to the image sensor array and disposed between an object (6) to be imaged and the image sensor array, at least one microlens (30) being assigned to each image sensor unit (20).

2. Device according to claim 1, wherein the microlenses (30) are aligned relative to each other in such a manner that the optical axes of the microlenses extend in parallel.

3. Device according to claim 1, wherein the microlenses (30) are aligned such that the optical axes of the microlenses in the centre of the image sensor array (2) are perpendicular to the at least one assigned light-sensitive surface and the optical axes of the microlenses are increasingly inclined from the centre to one edge relative to the assigned light-sensitive surface.

4. Device for optical navigation according to claim 1, wherein the microlenses (30) are configured such that an object section (60) which is imaged on a first image sensor unit is separate from an object section (60′) which is imaged on a second image sensor unit.

5. Device for optical navigation according to claim 1, wherein the image sensor array (2) is connected to the at least one microlens array (3, 3′, 3″) via an optically transparent substrate (21, 21′).

6. Device for optical navigation according to claim 1, wherein at least one pin diaphragm array (21, 22) is assigned to the image sensor array (2) and is disposed between image sensor array (2) and microlens array (3, 3′, 3″).

7. Device for optical navigation according to claim 1, wherein the microlenses (30) are disposed in at least two (3, 3″), microlens arrays, respectively at least one microlens of a first microlens array being aligned with at least one microlens of a second microlens array.

8. Device for optical navigation according to claim 7, wherein the first microlens array produces an intermediate image which is imaged by the second microlens array onto a common image plane, a further microlens array being inserted between the first and second microlens array as field lens array.

9. Device for optical navigation according to claim 8, wherein a Gabor superlens (101) is formed by the arrangement of the microlenses.

10. Device for optical navigation according to claim 1, wherein one image sensor unit (20) has precisely one light-sensitive surface and is assigned to precisely one microlens (30), the optical axes being essentially perpendicular to the light-sensitive surface.

11. Device for optical navigation according to claim 1, wherein individual optical channels between each image sensor unit and each corresponding assigned microlens are optically isolated.

12. Device for optical navigation according to claim 1, wherein the at least one microlens array (3, 3′, 3″) and the image sensor array (2) are connected at least in regions via spacers (34).

13. Device for optical navigation according to claim 1, wherein at least one incoherent or coherent optical radiation source (4) is assigned to the image sensor array and the radiation source (4) irradiates the object to be imaged (6).

14. Device for optical navigation according to claim 13, wherein the optical radiation source (4) is a light diode or a laser diode.

15. Device for optical navigation according to one of the claims 13 or 14, wherein the radiation source (4) irradiates the object by means of a lens system which decouple in the direction of the object.

16. Device for optical navigation according to claim 15, characterised wherein the image sensor array (2) is disposed on a carrier (5).

17. Device for optical navigation according to claim 16, wherein additional substrate layers are disposed between the carrier (5) and the image sensor array (2).

18. Device for optical navigation according to claim 1, wherein the image sensor (2) has a surface extension of 0.25 μm² to 10 mm².

19. Device for optical navigation according to claim 1, wherein the image sensor (2) has from 100 to 10,000 image sensor units.

20. Input device for a data processing unit, comprising a device for optical navigation having an image sensor array (2) with a large number of image sensor units (20, 20′) disposed in an array-like manner with respectively at least one light-sensitive surface and also at least one microlens array (3, 3′, 3″) which is assigned to the image sensor array and disposed between an object (6) to be imaged and the image sensor array, at least one microlens (30) being assigned to each image sensor unit (20).

21. Use of a device for optical navigation for controlling a cursor on an image output device by means of a relative movement between image sensor and object to be imaged, the device comprising image sensor array (2) with a large number of image sensor units (20, 20′) disposed in an array-like manner with respectively at least one light-sensitive surface and also at least one microlens array (3; 3′, 3″) which is assigned to the image sensor array and disposed between an object (6) to be imaged and the image sensor array, at least one microlens (30) being assigned to each image sensor unit (20).
